(19) United States
(12) Patent Application Publication
(10) Pub. No.: US 2003/0119277 A1
(43) Pub. Date: Jun. 26, 2003

(54) Semiconductor device manufacturing method

(76) Inventors: Takumi Shibata, Ichinomiya-Shi (JP); Toshiyuki Kamiya, Nagano-ken (JP)

Correspondence Address: EPSON RESEARCH AND DEVELOPMENT INC, INTELLECTUAL PROPERTY DEPT, 150 RIVER OAKS PARKWAY, SUITE 225, SAN JOSE, CA, 95134, US

(21) Appl. No.: 10/283,827

(22) Filed: Oct. 30, 2002

(30) Foreign Application Priority Data
Oct. 31, 2001 (JP) 2001-334686

(51) Int. Cl. H01L 21/76

(52) U.S. Cl. 438/424; 438/438

(57) ABSTRACT

A semiconductor device manufacturing method forms precision device isolation areas of a desirable minimum feature size in a semiconductor device having trench isolation areas. Steps include: (a) forming a polishing stopper layer 140 having a specific pattern on a semiconductor substrate 10; (b) forming trenches 16 in the semiconductor substrate 10 by etching using at least the polishing stopper layer 140 as a mask; (c) forming a protective layer 18 on the trench 16 surfaces; (d) causing the position of an edge part of the polishing stopper layer 14 to recede from the position of the trench 16 sidewalls; (e) forming an insulation layer 21 on the semiconductor substrate 10 so as to fill the trenches 16; and (f) forming trench isolation areas 30 by polishing the insulation layer 21 using the polishing stopper layer 14 as a stopper.

### BACKGROUND OF THE INVENTION

1. Field of the Invention

The present invention relates to a semiconductor device manufacturing method, and relates more particularly to a manufacturing method for a semiconductor device having device isolation areas.

2. Description of the Related Art

As the minimum feature size of such semiconductor devices as MOS transistors continues to get smaller, it has also become necessary to reduce the geometry of the device isolation areas. Forming device isolation areas using trench isolation techniques is being studied as a way to reduce device isolation area geometries. Trench isolation is a technique for separating semiconductor devices by forming trenches in the substrate between semiconductor devices and filling these trenches with an insulation material to isolate the semiconductor devices. A method of forming precise device isolation areas with a desired minimum feature size using this trench isolation technique is needed.

### OBJECTS OF THE INVENTION

An object of the present invention is therefore to provide a semiconductor device manufacturing method capable of forming precise device isolation areas with a desired minimum feature size.

### SUMMARY OF THE INVENTION

To achieve this object, a semiconductor device manufacturing method according to the present invention is a method for manufacturing semiconductor devices having trench isolation areas, and includes steps for: (a) forming a polishing stopper layer having a specific pattern on a semiconductor substrate; (b) forming trenches in the semiconductor substrate by etching using at least the polishing stopper layer as a mask; (c) forming a protective layer on the trench surfaces; (d) causing the position of the edge part of the polishing stopper layer to recede from the position of the trench sidewalls; (e) forming an insulation layer on the semiconductor substrate so as to fill the trenches; and (f) forming trench isolation areas by polishing the insulation layer using the polishing stopper layer as a stopper.

A semiconductor device manufacturing method according to this invention can thus prevent voids from occurring in the insulation layer filled into the trenches without degrading the shape of the device formation areas, and can therefore form precise device isolation areas with a desirable minimum feature size.

Preferably, step (c) in this semiconductor device manufacturing method forms the protective layer by thermal oxidation of the trench surfaces.

Yet further preferably, step (d) in this semiconductor device manufacturing method causes the position of the edge part of the polishing stopper layer to recede from the position of the trench sidewalls using dry etching.

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings wherein like reference symbols refer to like parts.

FIG. 1 is a section view schematically showing a step in a semiconductor device manufacturing method according to an embodiment of the invention.

FIG. 2 is a section view schematically showing a step in a semiconductor device manufacturing method according to an embodiment of the invention.

FIG. 3 is a section view schematically showing a step in a semiconductor device manufacturing method according to an embodiment of the invention.

FIG. 4 is a section view schematically showing a step in a semiconductor device manufacturing method according to an embodiment of the invention.

FIG. 5 is a section view schematically showing a step in a semiconductor device manufacturing method according to an embodiment of the invention.

FIG. 6 is a section view schematically showing a step in a semiconductor device manufacturing method according to an embodiment of the invention.

FIG. 7 is a section view schematically showing a step in a semiconductor device manufacturing method according to an embodiment of the invention.

FIG. 8 is a section view schematically showing a step in a semiconductor device manufacturing method according to an embodiment of the invention.

FIG. 9 is a section view schematically showing the formation of device isolation areas using a common trench isolation technique.

### DESCRIPTION OF THE PREFERRED EMBODIMENTS

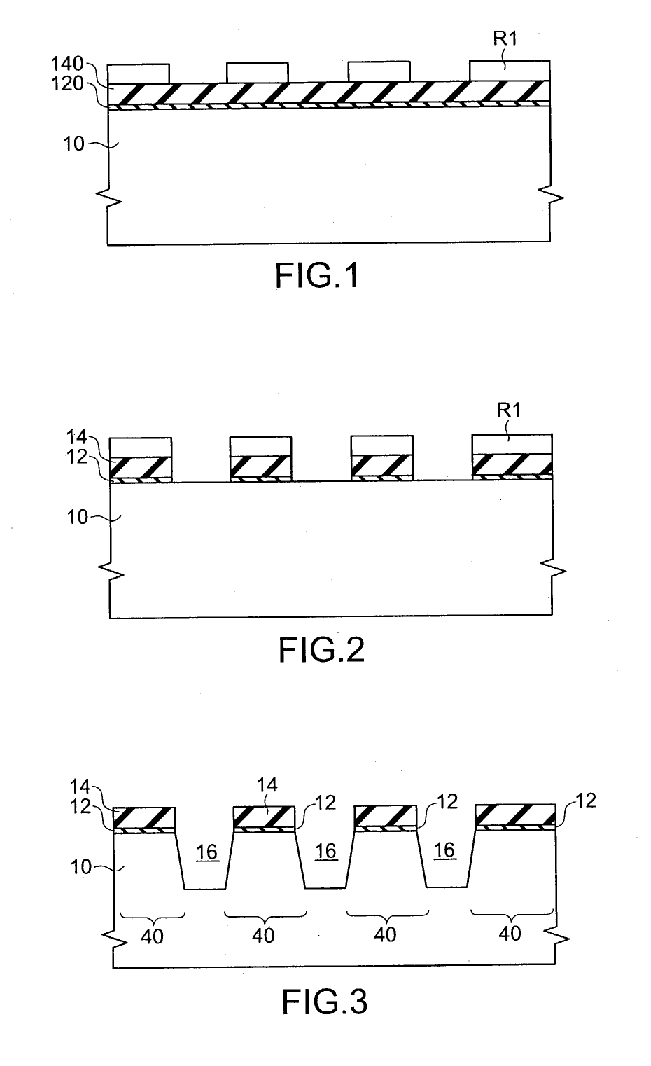

A manufacturing process for a semiconductor device according to a preferred embodiment of the present invention is described with reference to the accompanying figures. FIG. 1 to FIG. 8 are section views schematically describing the steps in a semiconductor device manufacturing process according to this preferred embodiment of the invention.

(1) Referring first to FIG. 1, a padding layer 120 is formed on a silicon substrate 10. Silicon dioxide, silicon oxynitride, or other such material can be used as the padding layer 120. A silicon dioxide padding layer 120 can be formed using thermal oxidation, CVD, or other method. A silicon oxynitride padding layer 120 can be formed by CVD, for example.

A polishing stopper layer 140 is then formed over the padding layer 120. The polishing stopper layer 140 can have a single layer or a multiple layer structure. A silicon nitride layer, polycrystalline silicon layer, or amorphous silicon layer, for example, can be used to form a single layer structure. A multiple layer structure can be formed using at least two types of silicon nitride, polycrystalline silicon, or amorphous silicon materials. A known method such as CVD can be used to form the polishing stopper layer 140. The polishing stopper layer 140 is formed to a film thickness sufficient to function as a stopper layer in a subsequent CMP process.

A resist layer R1 is then formed in a specific pattern on the polishing stopper layer 140.

(2) The polishing stopper layer 140 and padding layer 120 are then etched using the resist layer R1 as a mask to form polishing stopper layer 14 and padding layer 12 each having a specific pattern as shown in FIG. 2. Dry etching can be used for this step.

(3) The resist layer R1 is then removed by, for example, ashing. Next, the silicon substrate 10 is etched using the polishing stopper layer 14 as a mask to form trenches 16 as shown in FIG. 3. Device formation areas 40 are formed by forming these trenches 16. These device formation areas 40 are the areas where devices are formed after the trench device isolation areas 30 (FIG. 8) are formed.

It should be noted that description of the device formation process is omitted herein.

The depth of the trenches 16 differs according to the device design, but is typically 3 nm to 50 nm. The silicon substrate 10 can be etched by dry etching. The device formation areas 40 preferably have a tapered shape when seen in the sectional view of FIG. 3. When the device formation areas 40 are thus tapered, filling in the trenches 16 with the insulation layer 21 (FIG. 6) is easier in the process described below. In order to form the device formation areas 40 with a taper, the trenches 16 are formed with the opposite taper when seen in the sectional view of FIG. 3.

While not shown in the figure, the edges of the padding layer 12 disposed between the silicon substrate 10 and polishing stopper layer 14 are etched as needed.

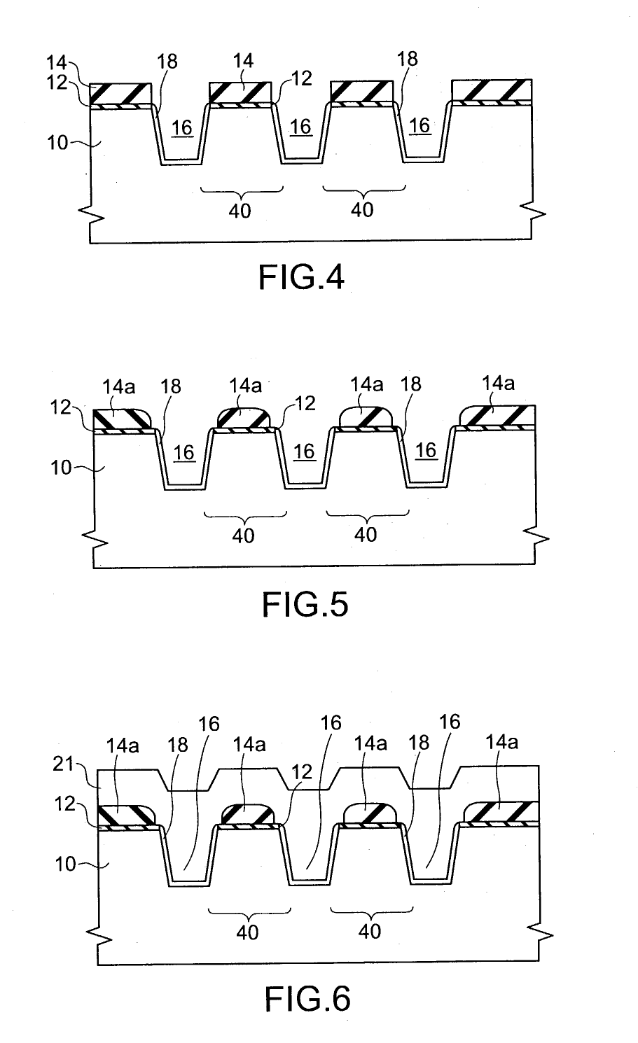

(4) A protective layer 18 of SiO₂ is then formed by oxidizing the exposed surfaces of the silicon substrate 10 inside the trenches 16 as shown in FIG. 4 by a thermal oxidation process. This protective layer 18 functions as a stopper layer when removing the edge parts of the polishing stopper layer 14 to form the structure of polishing stopper layer 14a shown in FIG. 5. More specifically, the protective layer 18 is provided to prevent etching the silicon substrate 10 and padding layer 12 in the process shown in FIG. 5 and described below for etching the edge parts of the polishing stopper layer 14a away from the position of the side walls of the trenches 16. The protective layer 18 is formed to a thickness of 3 nm to 50 nm, for example.

(5) Next, as shown in FIG. 5, polishing stopper layer 14a is formed by etching and removing the edge parts of the polishing stopper layer 14. This step leaves the edge of the polishing stopper layer 14a at a receded position offset from the position of the side walls of the trenches 16.

It should be noted that when the trenches 16 have an inverse taper in section view as described above, the edges of the polishing stopper layer 14 are removed by etching so that the edges of the resulting polishing stopper layer 14a are receded from the part at the outside-most part of the side walls of the trenches 16.

Anistropic dry etching using a CF₄—O₂—N₂ gas, for example, can be used in this step to etch the edges of the polishing stopper layer 14. NF₃ can also be used instead of CF₄ in the etching gas.

(6) An insulation layer 21 is then deposited over the entire surface as shown in FIG. 6 in order to fill the trenches 16. This insulation layer 21 is described as a SiO₂ layer in the present embodiment, but the material of the insulation layer 21 shall not be so limited and any material that can function as a trench isolation area can be used.

Furthermore, the thickness of the insulation layer 21 shall not be specifically limited insofar as the film thickness is sufficient to fill the trenches 16 and coat the polishing stopper layer 14. The insulation layer 21 can also be deposited using such methods as high density plasma CVD (HDP-CVD), thermal CVD, and TEOS plasma CVD.

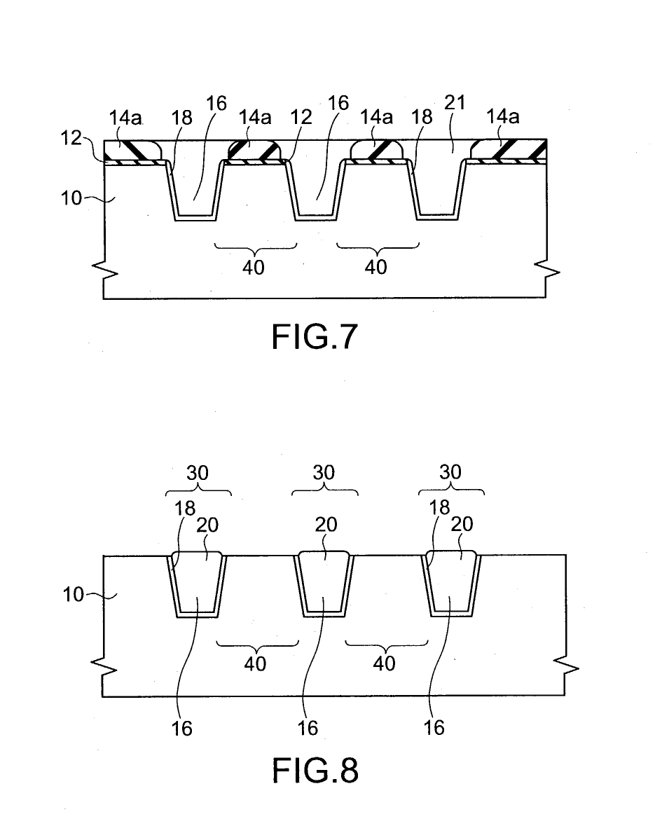

(7) The insulation layer 21 is then planarized by CMP as shown in FIG. 7. This planarization step continues until the polishing stopper layer 14 is exposed. In other words, the polishing stopper layer 14 functions as a stopper for planarizing the insulation layer 21.

(8) After next removing the polishing stopper layer 14 using a hot phosphoric acid solution, the top of the insulation layer 21 and padding layer 12 are isotropically etched with hydrofluoric acid. These steps thus form a trench isolation layer 20 in the trenches 16 and complete formation of trench isolation areas 30 as shown in FIG. 8.

(Operation and Effects)

The operation and effect of the semiconductor device manufacturing method according to the embodiment of the present invention described above are described below after first describing a general semiconductor device manufacturing method.

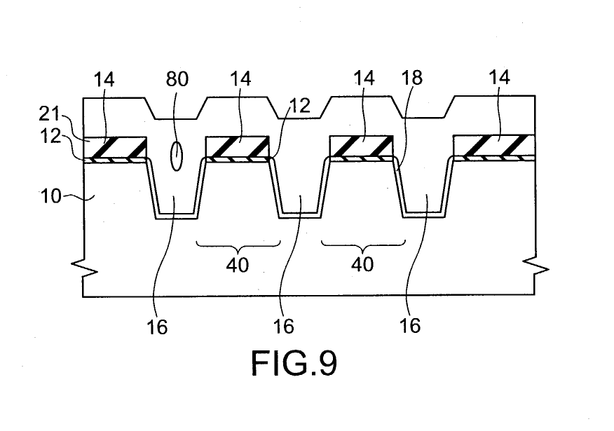

To ability to form precise device isolation areas is needed in the fabrication of general semiconductor devices as described above. It is also necessary to form trenches with a narrow width in order to form isolation areas with such a small geometry device. A problem here is that in the step for filling the trenches with an isolation layer after forming the narrow trenches, the insulation material cannot completely fill the trenches without gaps occurring, and voids 80 result in the insulation layer 21 as shown in FIG. 9. If voids 80 are thus formed in the insulation layer 21 many devices with poor electrical characteristics, such as lower insulation performance, result.

The semiconductor device manufacturing method of the present invention resolves this problem by etching and removing the edge parts of the polishing stopper layer 14 so that the edge part of the polishing stopper layer 14a is located at a position offset away from the sidewalls of the trenches 16, and the trenches 16 are then filled with insulation layer 21. In other words, this process first increases the size of the opening in the polishing stopper layer 14a formed at the top of the trenches 16, and then fills the trenches 16 with the insulation layer 21. This enables the insulation layer 21 to reliably fill the trenches 16 without voids occurring therein.

Yet further, the semiconductor device manufacturing method according to this embodiment of the invention forms a protective layer 18 on the surface of the trenches 16 before etching the edges of the polishing stopper layer 14 back from the trench sidewalls. This prevents the silicon substrate 10 and padding layer 12 from also being etched when the position of the edge parts of the polishing stopper layer 14 is removed from the trench sidewalls by etching in the step shown in FIG. 5. This also prevents deforming the shape of the device formation areas 40.

As described above, a semiconductor device manufacturing method according to this embodiment of the invention can therefore prevent voids occurring in the insulation layer 21 filled to the trenches 16 without degrading the shape of the device formation areas 40, and can therefore form precise device isolation areas with a desirable minimum feature size.

Although the present invention has been described in connection with the preferred embodiments thereof with reference to the accompanying drawings, it is to be noted that various changes and modifications will be apparent to those skilled in the art.

For example, a bulk silicon substrate is described for the semiconductor substrate in the preferred embodiment described above, but various other substrates can be used, including SOI, GaAs, InP, aluminum oxide, diamond, SiC, and substrates formed with multiple layers of these materials.

Such changes and modifications are to be understood as included within the scope of the present invention as defined by the appended claims, unless they depart therefrom.

While the invention has been described in conjunction with several specific embodiments, it is evident to those skilled in the art that many further alternatives, modifications and variations will be apparent in light of the foregoing description. Thus, the invention described herein is intended to embrace all such alternatives, modifications, applications and variations as may fall within the spirit and scope of the appended claims.

What is claimed is:

1. A manufacturing method for a semiconductor device having trench isolation areas, the manufacturing method comprising steps for:
(a) forming a polishing stopper layer having a specific pattern on a semiconductor substrate;
(b) forming trenches in the semiconductor substrate by etching using at least the polishing stopper layer as a mask;
(c) forming a protective layer on the trench surfaces;
(d) causing the position of an edge part of the polishing stopper layer to recede from the position of the trench sidewalls;
(e) forming an insulation layer on the semiconductor substrate so as to fill the trenches; and
(f) forming trench isolation areas by polishing the insulation layer using the polishing stopper layer as a stopper.

2. A semiconductor device manufacturing method as described in claim 1, wherein step (c) forms the protective layer by thermal oxidation of trench surfaces.

3. A semiconductor device manufacturing method as described in claim 1, wherein step (d) causes the position of the edge part of the polishing stopper layer to recede from the position of the trench sidewalls using dry etching.

4. A semiconductor device manufacturing method as described in claim 2, wherein step (d) causes the position of the edge part of the polishing stopper layer to recede from the position of the trench sidewalls using dry etching.
